(19) United States
(12) Patent Application Publication
(10) Pub. No.: US 2019/0310508 A1
(43) Pub. Date: Oct. 10, 2019

(54) DISPLAY DEVICE

(71) Applicant: SHARP KABUSHIKI KAISHA, Osaka (JP)

(72) Inventors: OSAMU ITOH, Sakai City (JP); KOHEI OKU, Sakai City (JP)

(21) Appl. No.: 16/374,093

(22) Filed: Apr. 3, 2019

(30) Foreign Application Priority Data
Apr. 6, 2018 (JP) 2018-073705

(51) Int. Cl. G02F 1/1345; H05K 1/18

(52) U.S. Cl. CPC G02F 1/13452; H05K 2201/10136; H05K 1/189

(57) ABSTRACT

A display device includes a display panel displaying an image, a control circuit board spaced apart from the display panel and supplying an input signal to the display panel, and a plurality of flexible boards each having a first end bonded on the display panel and a second end bonded on the control circuit board to perform electrical connection between the display panel and the control circuit board. The flexible boards further includes at least one set of paired flexible boards including two flexible boards in pairs, and the paired flexible boards are bonded between the display panel and the control circuit board in a crossed manner.

### CROSS REFERENCE TO RELATED APPLICATION

This application claims priority from Japanese Patent Application No. 2018-73705 tiled on Apr. 6, 2018. The entire contents of the priority application are incorporated herein by reference.

### TECHNICAL FIELD

The technology described herein relates to a display device.

### BACKGROUND

Patent Literature 1 below discloses a display device including a display panel that displays an image, a control circuit board (printed board) that supplies an input signal to the display panel, and flexible boards for electrical connection between the display panel and the control circuit board. The display device disclosed in the Patent Literature 1 below is intended to ensure a space in a longitudinal direction of the printed board for arranging other components therein, and is configured to connect the display panel and the printed board while the flexible boards extend obliquely relative to the printed board whose width is smaller than that of the display panel.

[Patent Literature 1] Japanese Patent Application Publication No. 2014-186162A

The flexible boards are bonded on the display panel and the control circuit board across an anisotropic conductive film (ACF) by applying pressure at high temperatures. Accordingly, the display panel, the control circuit board, and the flexible boards are subjected to thermal expansion immediately after the flexible boards are bonded, and thereafter contract while the temperature return to room temperatures. Moreover, since the display panel, the control circuit board, and the flexible boards have different amounts of contraction, the flexible boards may bend, and additionally stress caused by the contraction of the flexible boards may be exerted on the display panel to generate uneven image display on the display panel

### SUMMARY

The technology described herein was made in view of the above circumstances. An object is to obtain suppressed bending of bonded flexible boards as well as reduced stress applied to a display panel.

A display device according to the present invention includes a display panel, a control circuit board, and flexible boards. The display panel displays an image. The control circuit board is spaced apart from the display panel, and supplies an input signal to the display panel. The flexible boards each have a first end bonded on the display panel and a second end bonded on the control circuit board to perform electrical connection between the display panel and the control circuit board. The flexible boards include at least one set of paired flexible boards made by two flexible boards in pairs. The paired flexible boards are bonded between the display panel and the control circuit board in a crossed manner.

The display device configured. in such a manner as above includes the paired flexible boards that extend so as to intersect each other. Accordingly, longer flexible boards are obtainable than the currently-used. flexible boards that are arranged between the display panel and the control circuit board so as to extend nearly in a direction orthogonal to a direction along the display panel and the control circuit board. Consequently, the display device with such a configuration achieves absorption of difference in contraction amount between the display panel and the control circuit board with the elongated flexible boards, leading to suppressed force caused by the difference in contraction amount among them.

According to the technology described herein, suppressed bending of the bonded flexible boards as well as reduced stress applied to the display panel are obtainable.

### BRIEF DESCRIPTION OF THE DRAWINGS

FIG. 1 is a plan view of a display device according to a first embodiment.

FIG. 2 is an enlarged sectional view of a principal part of the display device (an A-A section in FIG. 1) according to the first embodiment.

FIG. 3 is a plan view of a currently-used display device.

FIG. 4 is a plan view of a display device according to a second embodiment.

FIG. 5 is an enlarged sectional view of a principal part of the display device (a B-B section in FIG. 4) according to the second embodiment.

### DETAILED DESCRIPTION

The following describes several examples of the present invention as modes to carry out the present invention with reference to the drawings. Note that the present invention is not intended to be limited to the embodiments described below, and may be exemplified with various modifications and various improved aspects on the basis of the knowledge of those skilled in the art.

### First Embodiment

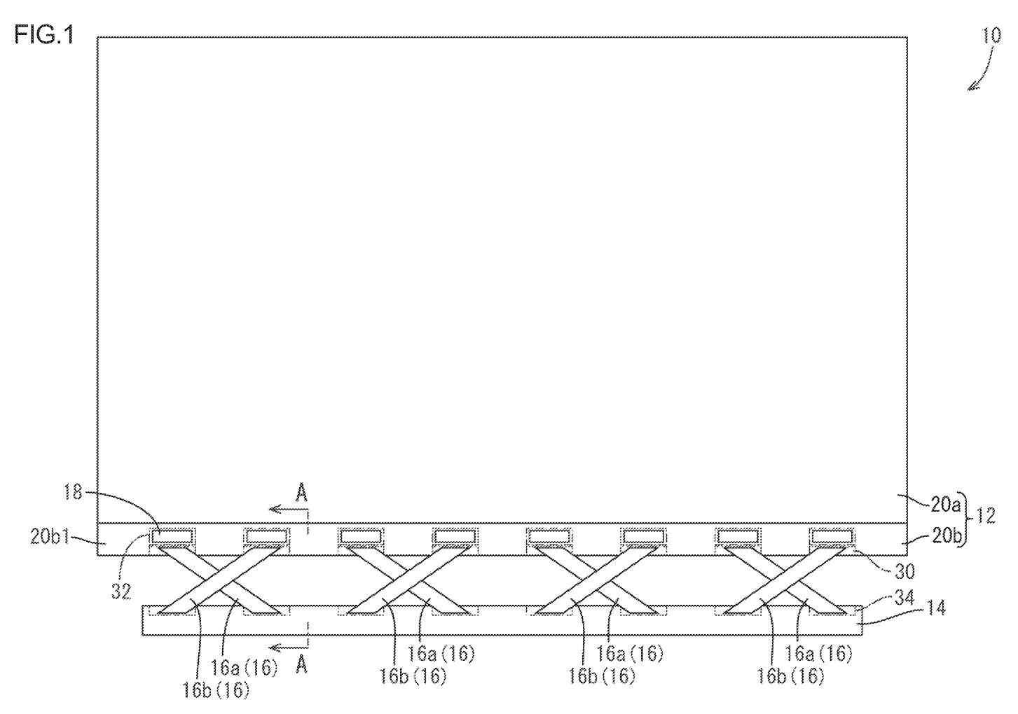

FIG. 1 is a plan view of a liquid crystal display device as a display device according to a first embodiment. As illustrated in FIG. 1, the liquid crystal display device 10 is horizontally rectangular in its entirety. The liquid crystal display device 10 includes a liquid crystal panel 12 as a display panel that is capable of displaying an image, a control circuit board 14 that supplies an input signal to the liquid crystal panel 12 externally of the liquid crystal panel 12, a plurality of flexible boards 16 that performs electrical connection between the liquid crystal panel 12 and the control circuit board 14, and a back light device (illustration abbreviated) that is disposed on a backside of the liquid crystal panel 12 and illuminates the liquid crystal panel 12 with light for displaying the image. The liquid crystal display device is used, for example, as a display for a television or a personal computer (PC). However, this is not limitative.

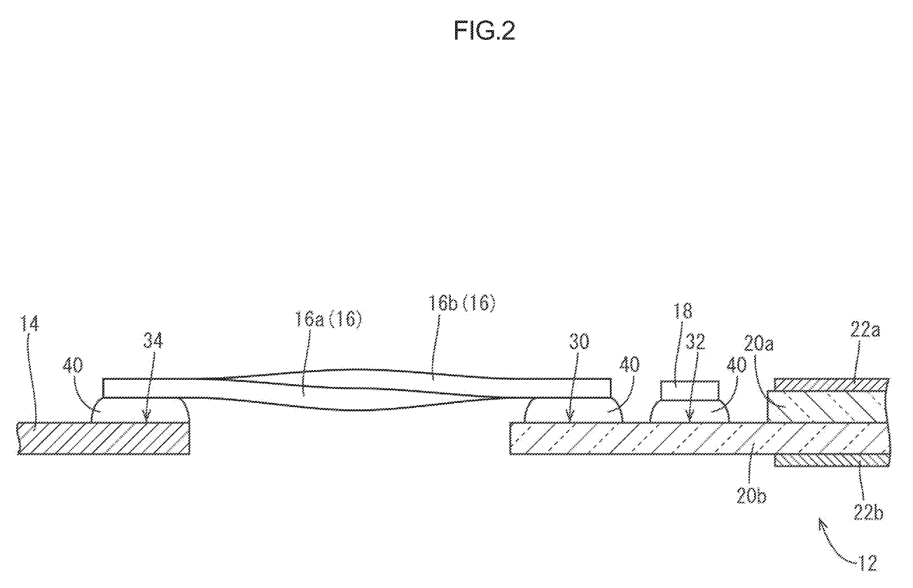

The liquid crystal panel 12 includes paired substrates 20a, 20b that are substantially transparent with excellent translucent. An upper side (surface side) of the paired substrates 20a, 20b is referred to as a CF substrate 20a, whereas a lower side (rear side) thereof is referred to as an array substrate 20b. Paired polarizers 22a, 22b adhere to outer faces of the paired substrates 20a, 20b, respectively (see FIG. 2). Moreover, the liquid crystal panel 12 includes paired substrates 20a, 20b that adhere to each other by a given gap. The liquid crystal panel 12 includes a liquid crystal layer and a sealing part (each illustration abbreviated). The liquid crystal layer contains liquid crystal molecules that are sandwiched between the paired substrates 20a, 20b and whose optical property is variable depending on electric field application. The sealing part surrounds and seals the liquid crystal layer. Here, as illustrated in FIG. 1, the array substrate 20b is larger than the CF substrate 20a. One longitudinal side of the array substrate 20b (a lower side in FIG. 1) extends outward from the CF substrate 20a, which extension portion is referred to as a CF substrate non-overlapped portion 20b1. A plurality of drivers (IC chips) 18 (eight in the present embodiment) that cause the liquid crystal panel 12 to drive and the flexible boards 16 mentioned above are bonded on the CF substrate non-overlapped portion 20b1. Note that, although the same number of the flexible boards 16 as the number of the drivers 18 is arranged correspondingly, the number of flexible boards may differ from the number of the drivers 18.

Simple description is made as under to an interior configuration of the liquid crystal panel 12. The CF substrate 20a and the array substrate 20b each include various films laminated on an internal face of a glass substrate. The laminated films cause arrangement of thin film transistors (TFT) as switching elements and pixel electrodes in a matrix array (in a row and column manner) at an interior side of the array substrate 20b. In addition, gate lines and source lines in a grid shape surround the TFTs and the pixel electrodes at the interior side of the array substrate 20b. The gate lines and the source lines receive signals concerned to images, respectively. In contrast to this, the CF substrate 20a includes at an interior side thereof a large number of color filters with three colors of read (R), green (G), and blue (B) alternately at positions corresponding to the pixel electrodes.

Next, the components connected to the liquid crystal panel 12 will be described. In the control circuit board 14, an electronic component for supplying various types of input signals to the drivers 18 is bonded on the substrate made from paper phenol resin or glass epoxy resin, and additionally a wiring part (conductive path) a given pattern is routed.

The flexible boards 16 each include a substrate made from a synthetic resin material (e.g., polyimide resin) with insulative and flexible properties on which a large number of wiring patterns are arranged. The flexible boards 16, which is to be described in detail later, each have a first end connected to the control circuit board 14, and a second end connected to the array substrate 20b of the liquid crystal panel 12 in a longitudinal direction. At the both ends of the flexible boards 16 in the longitudinal direction, wiring patterns are exposed externally to form terminals. The terminals are each electrically connected to the control circuit board 14 and the array substrate 20b. This allows transmission of the input signals from the control circuit board 14 to the liquid crystal panel 12.

The drivers 18 each operate in accordance with a signal supplied from the control circuit board 14. Consequently, the drivers 18 process the input signal from the control circuit board 14 to generate an output signal, and supplies the output signal to a display area of the liquid crystal panel 12. The drivers 18 are each subjected to chip on glass (COG) bonding on the CF substrate non-overlapped portion 20b1 of the array substrate 20b along a longitudinal side of the array substrate 20b.

The following describes connection of the drivers 18 and the flexible boards 16 to the array substrate 20b as well as connection of the flexible boards 16 to the control circuit board 14. As illustrated in FIG. 1, on the CF substrate non-overlapped portion 20b1 of the array substrate 20b, a plurality of flexible board bonding sections 30 (eight in the present embodiment) and a plurality of driver bonding sections 32 (eight in the present embodiment) are arranged along the longitudinal side of the array substrate 20b. The flexible board bonding sections 30 are used for bonding the flexible boards 16 at an outer circumference side of the CF substrate non-overlapped. portion 20b1. The driver bonding sections 32 are disposed between die flexible board bonding sections 30 and the CF substrate 20a for bonding the drivers 18. Here, neither detailed description nor illustration is made. The flexible board bonding sections 30 on the array substrate 20b correspond to terminals for receiving the input signals and power from the flexible boards 16 (for outputting the signals from the flexible boards 16 to the drivers 18.) Moreover, the driver bonding sections 32 on the array substrate 20b each include a driver input terminal that inputs the signal from the flexible board 16 to the driver 18, and a driver output terminal that outputs the signal from the driver 18 to the display area of the liquid crystal panel 12. The flexible board bonding sections 30 are electrically connected to the driver input terminal via connection wiring that are routed among them.

Moreover, a plurality of flexible board bonding sections 34 (eight in the present embodiment) are arranged in a longitudinal direction on the control circuit board 14 for bonding the flexible boards 16, respectively. The flexible board bonding sections 34 on the control circuit board. 14 are terminals for outputting signals or supplying power to the flexible boards 16.

On the other hand, although neither detailed description nor illustration is made, the flexible board 16 includes a first end where a flexible board output bump formed by a plurality of terminals electrically connected to the array substrate 20b is arranged, and a second end where a flexible board input bump formed by a plurality of terminals electrically connected to the control circuit board 14 is arranged. Moreover, the drivers 18 each include a driver input bump electrically connected to a driver input terminal of the array substrate 20b, and a driver output bump electrically connected to a driver output. terminal of the array substrate 20b.

Moreover, an anisotropic conductive film (ACF) 40 is used for connection between the driver 18 and the flexible board 16 to the array substrate 20b and connection between the flexible board 16 and the control circuit board 14. The ACF 40 is composed of a large number of conductive particles and a binder where the conductive particles are dispersed and compounded. The terminals adjacent to the array substrate 20b and the terminals adjacent to the control circuit board 14 are conducted to the bumps adjacent to the flexible board 16 and the driver 18 via the conductive particles. Then, such connection via the ACF 40 is made by applying pressure at high temperatures between the terminals and the bumps to be connected across the ACF 40.

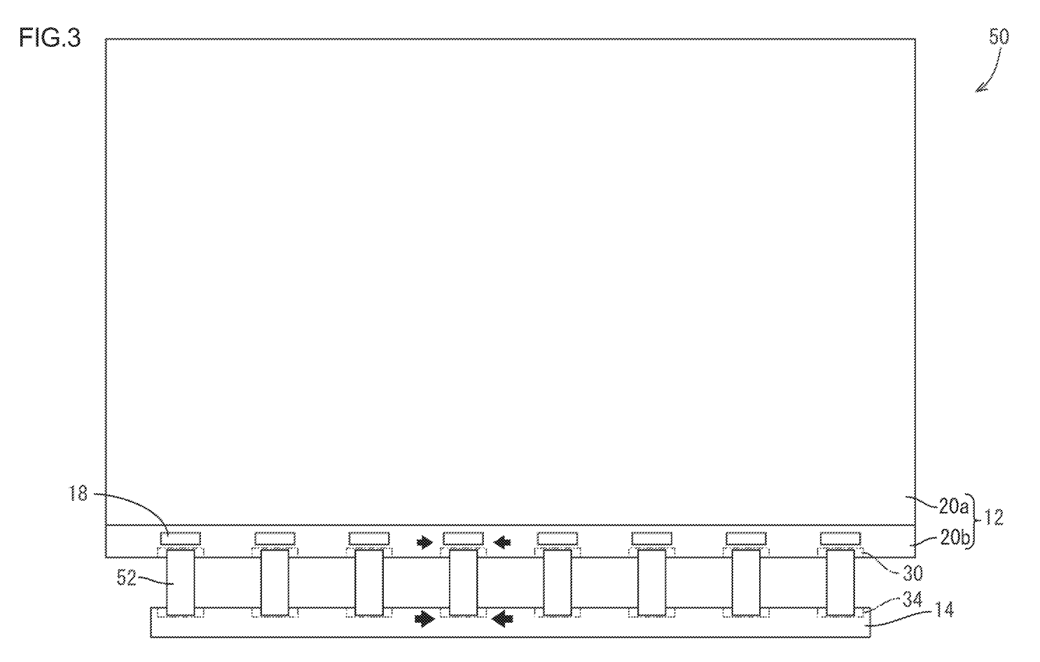

According to the connection method described above, when the flexible boards 16 are bonded on the array substrate 20b and the control circuit board 14, the control circuit board 14, the flexible hoards 16, and the array substrate 20b are subjected to thermal expansion. Thereafter, the control circuit board 14, the flexible boards 16, and the array substrate 20b contract while the temperature returns to the room temperature. However, the contraction amount differs among them, leading to certain drawbacks. For instance, in the currently-used liquid crystal display device 50 as illustrated in FIG. 3, a plurality flexible board bonding sections 30 of the array substrate 20b and a plurality of flexible board bonding sections 34 of the control circuit board 14 are connected via a plurality of flexible boards 52 so as to face each other. In such a current-used liquid crystal display device 50, the control circuit board 14, the flexible boards 52, and the array substrate 20b have different contraction amounts, leading to a possibility that the flexible boards 52 may bend. Moreover, since the control circuit board 14 has the contraction amount larger than that of the array substrate 20b, the difference in contraction amount generates stress, which may be exerted on the array substrate 20b to cause uneven image display on the liquid crystal panel 12.

The liquid crystal display device 10 in this embodiment includes a configuration that copes with the drawbacks as above. The following describes the configuration in detail. As illustrated in FIG. 1, the liquid crystal a display device 10 in this embodiment includes a plurality of flexible boards 16 having plural sets (four sets in this embodiment) of paired flexible boards made by two flexible boards in pairs. The two-paired flexible boards 16a, 16b are each a parallelogram, and axial symmetrical relative to each other. The flexible boards 16a, 16b are bonded between the array substrate 20b and the control circuit board 14 in a crossed manner. As for each of the paired flexible boards 16a, 16b, the flexible boards 16a, 16b are bonded while the flexible board bonding section 30 (hereunder, occasionally referred to as an “array substrate-side bonding section 30”) of the array substrate 20b and the flexible board bonding section 34 (hereunder, occasionally referred to as an “control circuit board-side bonding section 34”) of the control circuit board 14 are shifted along a clearance between the array substrate 20b and the control circuit board 14 (a direction along a longitudinal side of the array substrate 20b, a longitudinal direction of the control circuit board 14).

More specifically, the array substrate-side bonding section 30 and the control circuit board-side bonding section 34 face to each other across the clearance between the array substrate 20b and the control circuit board 14. In other words, the array substrate-side bonding section 30 and the control circuit board-side bonding section 34 are arranged in parallel in a direction where the liquid crystal panel 12 and the control circuit board 14 are arranged (a direction orthogonal to the longitudinal direction of the control circuit board 14 and to the longitudinal side of the array substrate 20b). Then, the paired flexible boards 16a, 16b are bonded in an X-shape with adjacent two array substrate-side bonding sections 30 and two control circuit board-side bonding sections 34 opposite thereto.

With such a configuration as above, the flexible boards 16 of the liquid crystal display device 10 in this embodiment are each longer than the flexible boards 52 in FIG. 3. Accordingly, even when each component contracts after the flexible boards 16 are bonded in the above-mentioned manner, the flexible boards 16 allow absorption of the difference in contraction amount between the array substrate 20b and the control circuit board 14. This achieves lowered stress exerted on the array substrate 20b.

In addition, in order to bond the one-paired flexible boards 16a, 16b as described above, the liquid crystal display device 10 in this embodiment includes the two array substrate-side bonding sections 30 and the two control circuit board-side bonding sections 34 that are arranged opposite to each other, and the one-paired flexible boards 16a, 16b are bonded in an X-shape. Accordingly, the flexible boards 16 are arranged regularly. This avoids a situation where the flexible boards 16 are bonded at improper positions, and also allows easy connection of the flexible boards 16 to the array substrate 20b and the control circuit board 14.

In the above-described embodiment, each flexible board 16 is made in a parallelogram shape so as to couple the array substrate 20b and the control circuit board 14 linearly. When the flexible board 16 is made longer than the flexible board 52 in FIG. 3, the flexible board 16 is not necessarily formed so as to couple the array substrate 20b and the control circuit board 14 linearly, but may be formed in various types of shapes such as one whose midpoint is bent or may be curved. Moreover, the number of the flexible boards 16 is not limited to the above-described number. In addition, a non-paired flexible board may be included. Furthermore, the display panel that the present invention adopts is not limited to the liquid crystal panel having the configuration described above. Alternatively, the liquid crystal panel with various types of configurations is applicable. For instance, an organic electro luminescence (EL) is applicable.

### Second Embodiment

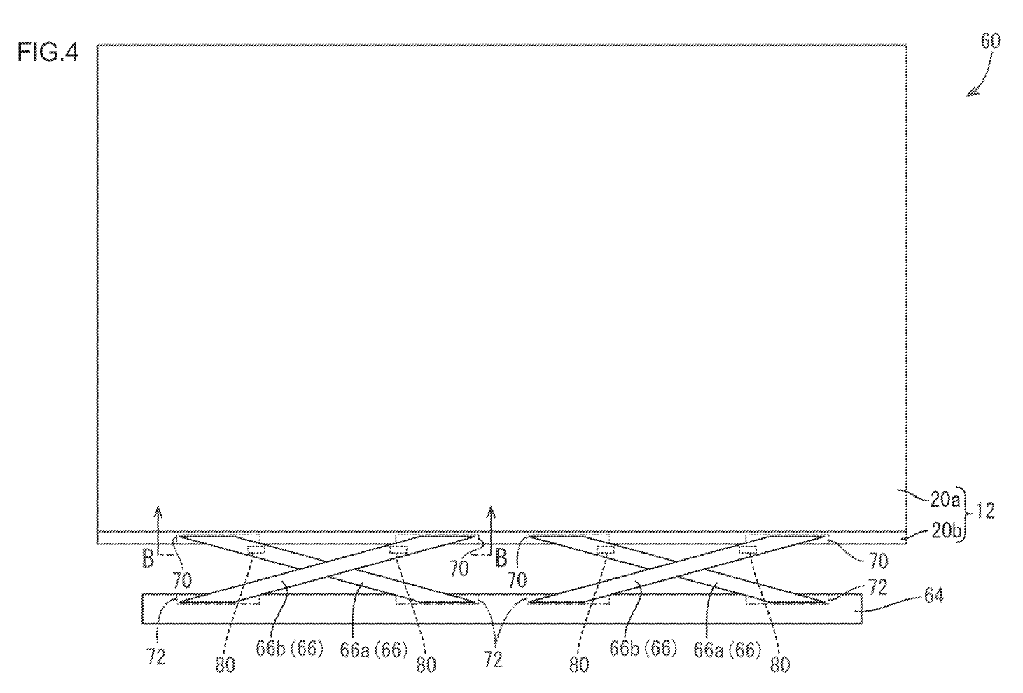

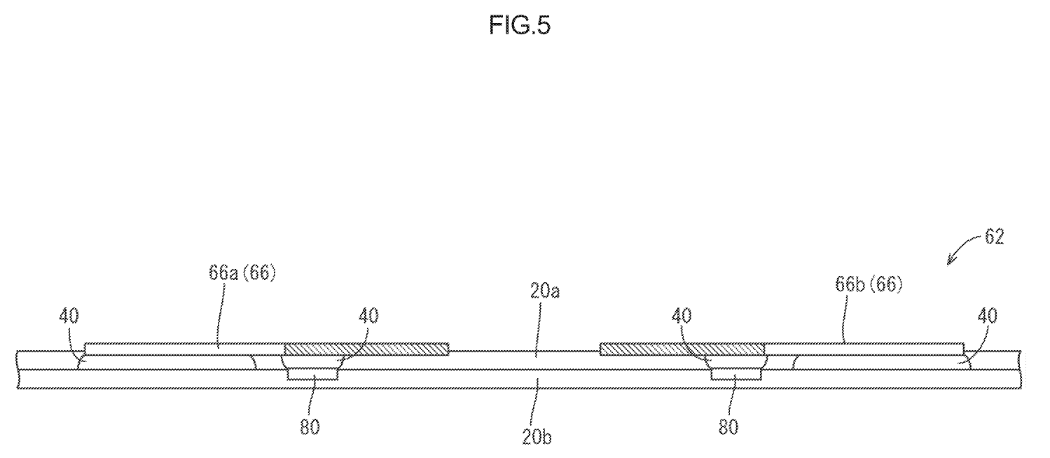

FIGS. 4 and 5 each illustrate a liquid crystal display device 60 according to a second embodiment. The liquid crystal display device 60 in this embodiment includes the same configuration as that of the liquid crystal display device 10 in the first embodiment except for a configuration of a portion where the flexible boards are bonded. Accordingly, same numerals are applied to the same parts as those of the liquid crystal display device 10 in the first embodiment, and thus the description thereof is to be omitted or to be made simply.

Similar to the liquid crystal display device 10 in the first embodiment, the liquid crystal display device 6 in this embodiment includes a liquid crystal panel 62, a control circuit board 64 that supplies an input signal to the liquid crystal panel 62 externally of the liquid crystal panel 62, a plurality of (four in this embodiment) flexible boards 66 that performs electrical connection between the liquid crystal panel 62 and the control circuit board 64. The liquid crystal panel 62 has the configuration substantially same as that of the liquid crystal panel 12 in the first embodiment, but differs from that of the liquid crystal panel 12 in number of flexible board bonding sections 70 that cause bonding of a first end of each of the flexible boards 66 arranged on the array substrate 20b. Moreover, the control circuit board 64 includes flexible board bonding sections 72 same in number as the flexible board bonding sections 70 of the array substrate 20b correspondingly. Then, similar to the liquid crystal display device 10 in the first embodiment, the liquid crystal display device 60 in this embodiment is formed by a plurality of flexible boards 66 having plural sets (two sets in this embodiment) of paired flexible boards 66a, 66b made by two flexible boards in pairs, and one-pared flexible boards 66a, 66b are bonded in a gap between the array substrate 20b and the control circuit board 64 in a crossed manner.

With such a configuration as above, similar to the liquid crystal display device 10 in the first embodiment, even when each component contracts after the flexible boards 66 are bonded in the above-mentioned manner, the flexible boards 66 allow absorption of the difference in contraction amount between the array substrate 20b and the control circuit board 64. This achieves lowered stress exerted on the array substrate 20b also in the liquid crystal display device 60 of this embodiment.

The liquid crystal display device 10 in the first embodiment includes a plurality of drivers 18 that are subjected to chip on glass (COG) bonding on the array substrate 20b. In contrast to this, the liquid crystal display device 60 in this embodiment includes drivers 80 same in number as that of the flexible boards 66, and the drivers 80 are subjected to chip on film (COF) bonding on the flexible boards 66. Then, the drivers 80 disposed on the paired flexible boards 66a, 66b are arranged at positions where the paired. flexible boards 66a, 66b do not overlap. This prevents overlap among the drivers 80 that generate heat, leading to avoidance of a lowered transmission speed and operation failure.

1. A display device comprising:
a display panel displaying an image;
a control circuit board spaced apart from the display panel and supplying an input signal to the display panel; and
a plurality of flexible boards each having a first end bonded on the display panel and a second end bonded on the control circuit board to perform electrical connection between the display panel and the control circuit board,
the flexible boards further including at least one set of paired flexible boards including two flexible boards in pairs, and
the paired flexible boards being bonded between the display panel and the control circuit board in a crossed manner.

2. The display device according to claim 1, wherein in the paired flexible boards, a position where the first end is bonded on the display panel and a position where the second end is bonded to the control circuit board are shifted along a clearance between the display panel and the control circuit board.

3. The display device according to claim 2, wherein the position where the first end of one of the paired flexible boards is bonded and the position where the second end of the other of the paired flexible boards is bonded are arranged in parallel in a direction where the liquid crystal panel and the control circuit board are arranged.

4. The display device according to claim 3, wherein the paired flexible boards are configured such that the position where the first end is bonded on the display panel and the position where the second end is bonded to the control circuit board are coupled linearly.

5. The display device according to claim 4, wherein the paired flexible boards are each a parallelogram.

6. The display device according to claim 1, wherein
the paired flexible boards include first and second drivers that each drive the display panel, and the first driver is bonded on a position not overlapping the other of the paired flexible boards where the second driver is bonded.
